(19) United States
(12) Patent Application Publication
(10) Pub. No.: US 2011/0254109 A1
(43) Pub. Date: Oct. 20, 2011

(54) INTEGRATED CIRCUIT WITH SPURRIOUS ACOUSTIC MODE SUPPRESSION AND METHOD OF MANUFACTURE THEREOF

(75) Inventors: William Ossmann, Acton, MA (US); Bernie J. Savord, Andover, MA (US); Jie Chen, North Andover, MA (US); Rod J. Solomon, Cape Coral, FL (US)

(73) Assignee: KONINKLIJKE PHILIPS ELECTRONICS N.V., EINDHOVEN (NL)

(21) Appl. No.: 13/141,853

(22) PCT Filed: Dec. 7, 2009
(86) PCT No.: PCT/IB2009/055554

§ 371 Date: Jun. 23, 2011

Related U.S. Application Data
(62) Division of application No. 61/140,293, filed on Dec. 23, 2008.

(51) Int. Cl. H01L 29/84; H01L 21/02

(52) U.S. Cl. 257/415; 438/50; 257/E29.324; 257/E21.002

(57) ABSTRACT

An integrated circuit (IC) apparatus includes a substrate having opposed first and second major sides and one or more edges defining an outer periphery of the substrate. The substrate may be a semiconductor material. The IC apparatus may further include one or more transducers situated on the first major side of the substrate; and an attenuation pattern formed in at least one of the second major side and one or more of the edges of the substrate.

The present system relates generally to integrated circuits with acoustic mode suppression, such as integrated transducer circuits, and, more particularly, to acoustic transducers fabricated integrally on an integrated circuit (IC) with spurious mode suppression, and a method of manufacture thereof.

Ultrasonic transducers are used for many purposes such as imaging, detection, etc. Typically, in ultrasonic transducers used for medical or other types imaging, acoustically active parts of these transducers can be directly fabricated on an integrated circuit (IC) or connected to an IC via a thin interconnection layer so as to save space and reduce cost and complexity. Ultrasonic transducers may be incorporated in capacitive micro-machined ultrasonic transducer (cMUT)- and piezo micro-machined ultrasonic transducer (pMUT)-arrays which are fabricated directly on silicon wafers (e.g., see, U.S. Pat. Nos. 6,430,109 and 6,493,288, which are incorporated herein by reference).

A disadvantage of fabricating the acoustically active parts of the transducer directly on the IC or silicon wafer is that the silicon wafer is situated between active elements (e.g., an acoustic stack) and any loss backing that may be present to attenuate unwanted acoustic vibrations. Unfortunately, as silicon (Si) substrates are poor attenuators of acoustic energy, without proper attenuation, spurious acoustic modes can be excited in the IC and result in unwanted artifacts in an image acquired via the IC.

Various methods are known to attenuate spurious acoustic modes. For example, U.S. Pat. No. 6,685,647 entitled “Acoustic Imaging Systems Adaptable for Use with Low Drive Voltages” to Savord et al., and incorporated herein by reference, uses an acoustic de-matching layer which is placed between a piezo-electric transducer (PZT) and a backing layer. The acoustic de-matching layer preferably exhibits an acoustic impedance that is greater than the acoustic impedance of the PZT. Although this impedance difference substantially prevents acoustic energy from propagating into the backing, invariably some acoustic energy can still propagate into the backing and cause a spurious acoustic mode to be excited.

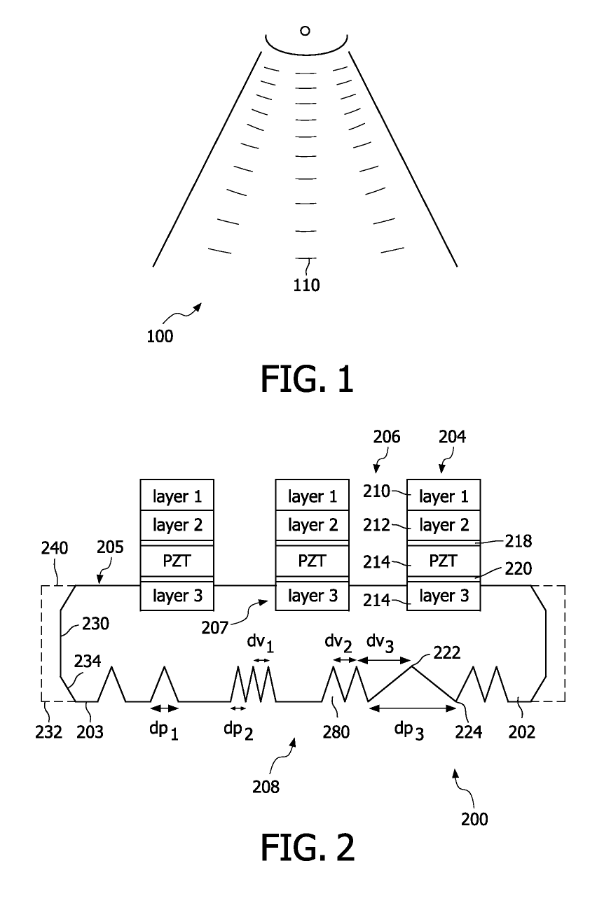

As the backing layer, such as silicon (Si), exhibit extremely low acoustic attenuation characteristics, the acoustic energy that leaks into the Si backing layer from, for example, an initial transmit pulse can be stored in the Si backing for 100 microseconds or longer. During this time, the stored energy can slowly leak back into the acoustic stack, and interfere with the received signals (e.g., echoes) and cause artifacts in an image. These artifacts may show up as a generalized haze or may have distinct spatial features such as lines at particular angles in the image. This is more clearly illustrated with reference to FIG. 1 which is an image 100 with artifacts 110 attributable to spurious acoustic modes in an Si backing within the transducer structure. Since the transmit pulse has an amplitude which is much larger than the received echoes, a high level of suppression must be achieved to eliminate the artifacts. Accordingly, there is a need for a system and a method to suppress spurious acoustic modes within a backing.

Suppressing spurious acoustic modes is important as acoustic energy stored in the backing may propagate laterally in any of a variety of loaded plate modes such as Lamb waves or surface waves. If the acoustic velocities of these modes are high enough, and the backing small enough, than many traverses of the backing can be made during the storage time (e.g., 100 microseconds or more). Accordingly, there is a need for a system and/or a method attenuating this acoustic energy.

One object of the present systems, methods, apparatus and devices is to overcome the disadvantages of conventional systems and methods. Accordingly, the present system provides a device and method for interfering with the propagation or otherwise inducing loss in excess of the naturally very low acoustic attenuation of an IC substrate material such as, for example, silicon (Si). Attenuation methods may include interfering with the propagation of the acoustic modes and/or by damping out the reflections at the edges of a substrate such as, an Si wafer.

As used herein, the term spurious signals will refer to undesirable signals which may be present in a substrate. Spurious signals may include, for example, noise signals, spurious acoustic modes, acoustic energy, acoustic noise, reflections, any of a variety of loaded plate modes such as Lamb waves or surface waves, bulk longitudinal, bulk shear, Lamb, Stonely, Love, Rayleigh, horizontal shear, and/or any other signals or guided wave modes that the structure supports, which are typically particular to the structure itself.

According to one illustrative embodiment, an integrated circuit (IC) apparatus includes a substrate having opposed first and second major sides and one or more edges defining an outer periphery of the substrate. The substrate may be a semiconductor material. The IC apparatus may further include one or more transducers situated on the first major side of the substrate; and an attenuation pattern formed in at least one of the second major side and one or more of the edges of the substrate.

Further areas of applicability of the present devices and systems and methods will become apparent from the detailed description provided hereinafter. It should be understood that the detailed description and specific examples, while indicating exemplary embodiments of the systems and methods, are intended for purposes of illustration only and are not intended to limit the scope of the invention.

These and other features, aspects, and advantages of the apparatus, systems and methods of the present invention will become better understood from the following description, appended claims, and accompanying drawing where:

FIG. 1 is an image with artifacts attributable to spurious acoustic modes in an IC or silicon substrate within a transducer structure;

FIG. 2 is a side view illustration of a transducer including a substrate according to an embodiment of the present system;

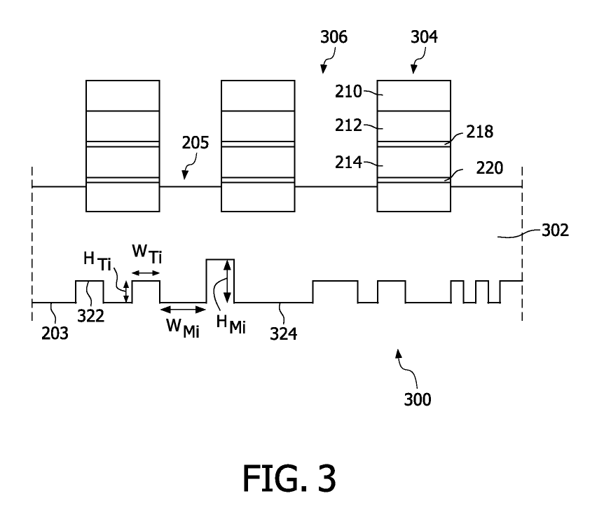

FIG. 3 is a side view illustration of a transducer including a substrate according to another embodiment of the present system;

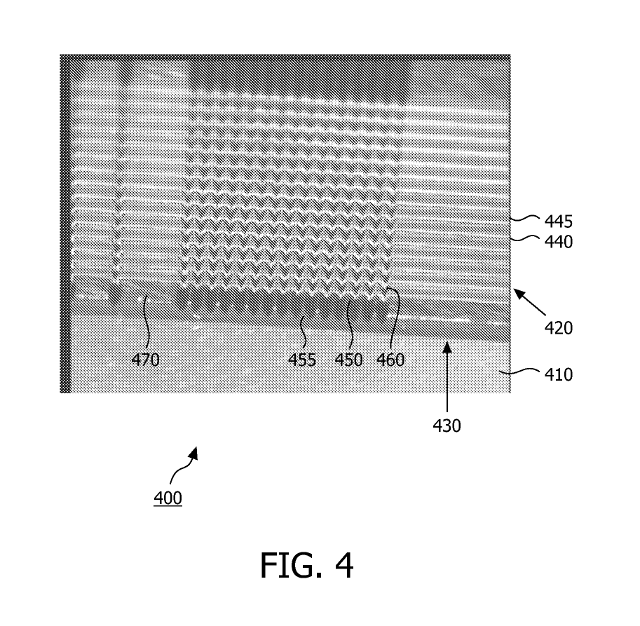

FIG. 4 is an elevated partial bottom view illustration of a substrate including an array of grooves according to an embodiment of the present system;

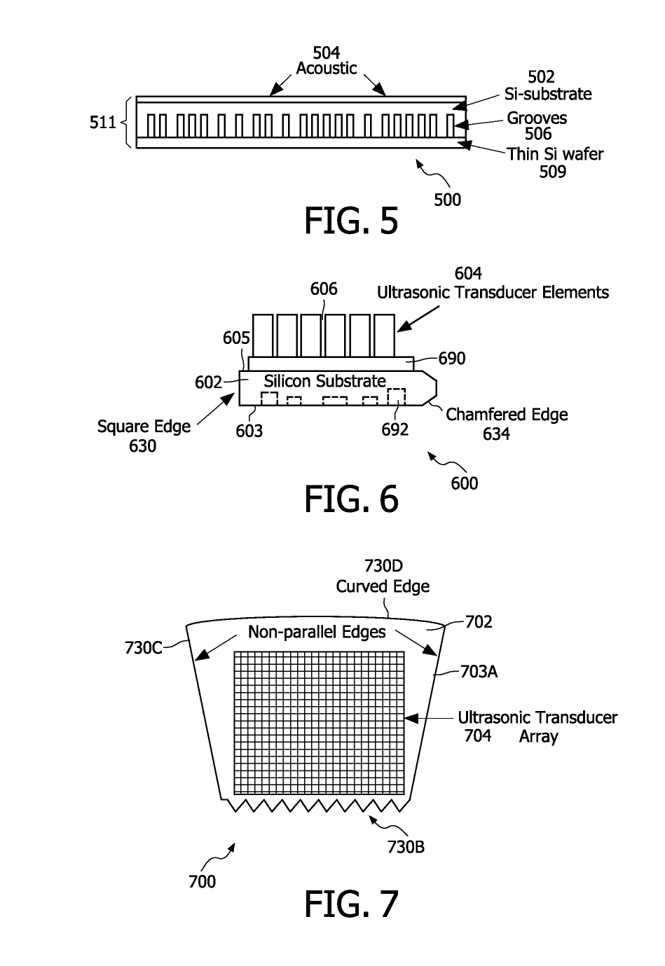

FIG. 5 is side view illustration of a composite substrate according to an embodiment of the present system;

FIG. 6 is side view illustration of a substrate with chamfers according to an embodiment of the present system;

FIG. 7 is top view illustration of a substrate with non-parallel sides according to an embodiment of the present system;

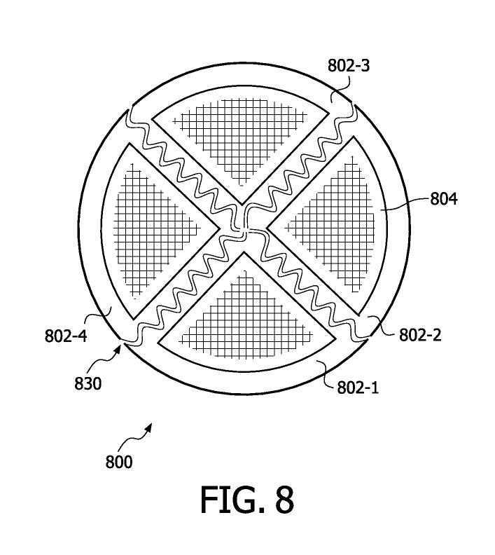

FIG. 8 is a top view illustration of a transducer array according to an embodiment of the present system; and

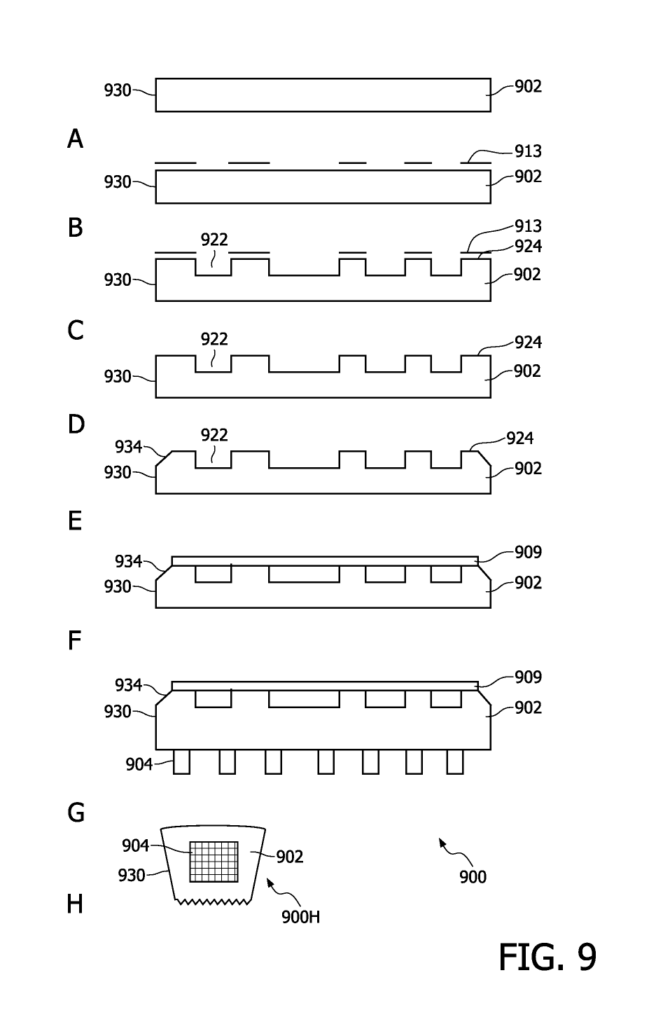

FIG. 9 shows a process of forming the transducer according to an embodiment of the present system.

The following description of certain exemplary embodiments is merely exemplary in nature and is in no way intended to limit the invention, its applications, or uses. In the following detailed description of embodiments of the present systems and methods, reference is made to the accompanying drawings which form a part hereof, and in which are shown by way of illustration specific embodiments in which the described systems and methods may be practiced. These embodiments are described in sufficient detail to enable those skilled in the art to practice the presently disclosed systems and methods, and it is to be understood that other embodiments may be utilized and that structural and logical changes may be made without departing from the spirit and scope of the present system.

The following detailed description is therefore not to be taken in a limiting sense, and the scope of the present system is defined only by the appended claims. The leading digit(s) of the reference numbers in the figures herein typically correspond to the figure number, with the exception that identical components which appear in multiple figures are identified by the same reference numbers. Moreover, for the purpose of clarity, detailed descriptions of certain features will not be discussed when they would be apparent to those with skill in the art so as not to obscure the description of the present system.

For the sake of clarity, only partial sections of transducers and/or substrates according to the present system may be shown in some illustrations.

A side view illustration of a transducer 200 including a substrate according to an embodiment of the present system is shown in FIG. 2. The transducer 200 includes one or more transducer elements 204, one or more trenches 206, and a substrate 202.

A plurality of the transducer elements 204 may be configured to form an array of transducer elements 204 which are configured on the substrate 202, as shown. Each transducer element 204 may include one or more piezoelectric elements such as, for example, a piezo-electric element (PZT) 214. Matching layers such as, for example, layers 210, 212 and 216 may be included to efficiently couple acoustic energy from the PZT 214 to the body. Accordingly as is well known, the layers 210, 212 and 216 may include conductive layers which may be patterned such as, for example, by saw cuts. In addition, two electrode layers 218, 220 may be provided at both sided of the PZT layer 214 which may be driven by a controller included in the substrate 202, etc.

Typical transducers include various elements such as electrodes and matching layers, where the design of matching layer structures for ultrasonic transducers is well known in the art, such as those described in U.S. Pat. No. 7,439,656 to Ossmann entitled “Method for Designing Ultrasonic Transducers with Acoustically Active Integrated Electronics,” and in U.S. Pat. No. 6,685,647 to Savord, et al. entitled “Acoustic Imaging Systems Adaptable for Use with Low Drive Voltages,” each of which is incorporated herein by reference in its entirety. It should be noted that in FIG. 2, although the transducer elements 204 are shown in a vertical orientation, one or more layers or parts thereof may be oriented in other positions such as, for example, horizontal.

The trenches 206 may be situated on one or more sides of each transducer element 204. The trenches 206 may have the same or different width and/or height from each other. Moreover, the trenches 206 may extend into and/or be formed from a part of the substrate 202.

The substrate 202 may have a top portion 205, a bottom portion 203, and may extend between one or more edges 230. The substrate 202 may be formed from one or more materials which are compatible with the transducers 204 mounted thereon. For example, the substrate 202 may be formed from a semiconductor material (e.g., silicon (Si), gallium arsenide, etc.), crystalline material (e.g., quartz or sapphire, etc.), ceramics (e.g., alumina, boron nitride, glass, etc.), metal (e.g., aluminum, brass, steel, copper, tungsten, titanium), and/or a wide variety of polymers including flexible and rigid printed circuits. The transducers 204 may be formed upon and/or attached to the top portion 205 of the substrate 202. Further, portions of the transducers 204 may be located in trenches 207 in the top portion 205 of the substrate 202.

The substrate 202 may include an attenuation pattern including one or more attenuators 208 which may have any suitable shape and/or size to properly attenuate spurious signals. For example, a plurality of the attenuators 208 may include grooves (or trenches) 280 which may be shaped and sized so as to form an array of angular surfaces with alternating low and high areas 222 and 224, respectfully, where the high areas 224 corresponding with a peak and the low areas each correspond with a valley. Although a difference in height between adjacent the peaks and valleys is shown as being equal to each other, the difference in height of adjacent peaks and valleys may also be unequal to each other. Moreover, the distance between adjacent peaks and/or valleys may be the same or may vary in one or more areas of the substrate 202. For example, dₚ₁ may vary in relation to dₚ₂ and/or dₚ₃. Likewise, dᵥ₁ may be vary in relation to dᵥ₂ and/or dᵥ₃.

The edges 230 of the substrate 202 may include suppression portions 232 to attenuate acoustic waves. The suppression portions 232 may include for example, chamfers 234 which are located along one or more edges 230 of the substrate 202. However, the suppression portions 232 may include other shapes such as, for example, rounds, roughened areas, tapers, uneven edges, and/or combinations thereof. For example, one edge 230 of the substrate 202 may include a single chamfered edge 234 and the opposite edge 230 may include two chamfered edges 234 as shown in FIG. 2. The chamfered edges 234 may cause interference between multiple reflections of a spurious signal. As chamfered edges 234 may be a less efficient reflector than a square edge, the chamfered edges 234 may attenuate acoustic reflections within the substrate 202. Accordingly, acoustic modes included in spurious signals may die out more quickly than in conventional substrates.

The substrate 202 may also include an acoustic damping material 240 which is located adjacent to one or more of the edges of the wafer. The damping material 240 may include any material which may dampen spurious signals which can include acoustic modes. For example, the damping material 240 may include loaded and/or unloaded epoxies, or curable elastomers such room temperature vulcanization rubbers (RTVs), etc. Thus, during use, on each reflection from an edge, the damping material 240 may absorb at least some spurious signal energy such as spurious acoustic modes so that they are attenuated quickly and do not interfere with received echoes during use.

Thus, by including suppression areas and materials at the edges of a substrate, spurious signals such as acoustic waves which may otherwise be reflected many times at the edges of the substrate without losing substantial energy, may be adequately attenuated so that they do not interfere with operation of the transducer 200 and/or other components on the substrate 202.

The dampening material 240 may also have chamfers at its edges. Further, it is also envisioned that the dampening material 240 may fill portions of the low areas 222 of the substrate 202 and may attenuate at least part of a spurious signal.

A side view illustration of a transducer 300 including a substrate according to another embodiment of the present system is shown in FIG. 3. The transducer 300 includes one or more transducer elements 304, one or more trenches 306, and a substrate 302. The transducer elements 304 and the trenches 306 may be similar to the transducer elements 204 and the trenches 206, respectively, shown in FIG. 2. Accordingly, for the sake of clarity, a further description of these elements will not be given. For example, one or more edges 430 of the substrate 302 may include one or more attenuating portions such as chamfer(s). Dampening material may also be provided over the edges similar to the dampening material 240 described in connection with FIG. 2

In contrast to FIG. 2, the substrate 302 shown in FIG. 3, which is similar to the substrate 202, may include one or more trenches 322 which define mesas 324. The width W_{Mi} and/or the height H_{Mi} of the mesas 324 and/or the width W_{Ti} (where i denotes an individual mesa or trench) and/or height H_{Ti} of the trenches 322 may be sized as desired. Thus, the width W_{Mi} and/or the height H_{Mi} of mesas 322 and/or the distance between mesas 322 can be may be adjusted so as to attenuate spurious signals of, for example, one or more frequencies, as desired. Likewise, the width W_{Ti} and/or height H_{Ti} of the trenches 322 may be adjusted so as to attenuate spurious signals of, for example, one or more frequencies, as desired.

Accordingly, by varying the distance and/or the height of adjacent mesas and/or trenches, the mesas and/or trenches can be tuned to attenuate corresponding frequencies. Accordingly, spurious signals including certain undesirable acoustic modes may be attenuated using the substrate according to the present system.

An elevated partial bottom view illustration of a grooved substrate 400, e.g., a silicon (Si) substrate, including an array of grooves according to an embodiment of the present system is shown in FIG. 4. The grooved substrate 400 is an intermediate stage of manufacture of a transducer in which the substrate 400 is scored before assembly into the transducer. The substrate is lying face down on a support 410, such as a dicing tape, and has first and second set of grooves 420, 430 that intersect each other, e.g., are perpendicular to each other. For example, the first set of grooves 420 may extend in one or more first directions such that adjacent grooves may not be parallel to each other.

Likewise, the second set of grooves 430 may extend in another direction or directions such that the second groove(s) 430 intersect(s) with one or more of the first grooves 420. The first set of grooves 420 may define one or more peaks 440 and valleys 445 in the substrate, and the second set of grooves 430 may define one or more peaks 450 and valleys 455 in the substrate.

In those portions where the first and second sets of grooves 420, 430 intersect with one another, an array of peaks and valleys form, for example, objects such as pyramid shaped portions 460 may be formed. Although pyramid shaped objects 460 are shown, the corresponding shapes may be defined by cross sections of corresponding areas of intersecting grooves. For example, although grooves 420, 430 having a “V” shaped cross section are shown, other one or more of the grooves and/or portions thereof may include other types of cross sections. For example, the cross sections may include square, rounded and/or “U” shaped areas. It is also envisioned that one or more of the grooves 420, 430 may extend partially across the substrate. Thus, a groove having a “U” cross section may be considered a trench.

One or more edges of the substrate may include one or more attenuating portions such as chamfer 470. Dampening material 470 may also be provided over the edges similar to the dampening material 240 described in connection with FIG. 2. It is also envisioned that any other suitable (random or non-random) patterns and/or textures (as opposed to, or in addition to the grooves 420, 430) may be located in the substrate to create incoherent reflections causing the spurious signals to die out more quickly than in conventional substrates.

The trenches, grooves, patterns, and/or textures may be formed in the substrate, such as in lower portion and/or edges of the substrate, using any suitable method. For example, suitable methods include chemical and/or mechanical methods. For example, one method of creating the grooves 420, 430, is to saw cut part way through the thickness of the substrate 400, in one or more different directions so as for form a textured array. Another method to texture the lower surface of the substrate 400 may include (randomly or non-randomly) etching into the lower surface of the substrate 400 using, for example, chemical and/or plasma etching.

The grooves 420, 430 or other patterns/textures formed on the substrate 400, (e.g., on its lower surface) may have similar and/or different shapes and may be repeated in regular and/or irregular/random intervals. For example, if it is desired that only a single frequency of spurious signals be attenuated, the grooves 420, 430 (or other patterns/textures) may be repeated in intervals which would attenuate this particular frequency. However, if it is desired that a plurality of frequencies of spurious signals be attenuated, then the grooves 420, 430 (or other patterns/textures) may be formed so as to form an irregular, random or asymmetric pattern to attenuate the desired frequencies. However, it is also envisioned that the grooves may be spaced apart from each other by a constant distance. However, in this case, care should be taken so that proper attenuation characteristics are established such that resonances for undesirable frequencies, which would otherwise be slow to die out because of constant spacing, are attenuated.

However, to attenuate a broad spectrum of frequencies, it may be desirable to form grooves or other textures that are irregularly spaced, and which may not be parallel to each other, so that their reflections are incoherent and interfere destructively so as to attenuate the spurious signals. In this way, the accelerated decay of modes of the spurious signals can be achieved. Other methods to form textures on the lower surface of the substrate may include sandblasting through a wire mesh, laser ablation, or chemical etching. Accordingly, the attenuation patterns on the back side of the substrate can be formed which may interfere with, and thus attenuate, the propagation of the spurious signals as they propagate through the substrate.

A side view illustration of a composite substrate according to an embodiment of the present system is shown FIG. 5. A transducer 500 (or parts thereof) may include a composite substrate 511 which may be formed by bonding or otherwise attaching a thin semiconductor wafer such as a Si wafer 509 to a substrate 502 so as to form the composite substrate 511. The substrate 502 may includes a noise attenuating portion including grooves 506 for attenuating spurious signals. An acoustic layer 504 is attached to a side of the substrate 502 where the thin semiconductor wafer 509 is attached. Depending upon the size of the grooves 506 and the thickness and size of the substrate 502, it may be difficult to process the substrate 502 during manufacture without the support provided by a composite substrate 511. Accordingly, in these situations, it may be desirable to use the composite substrate 511. Further, the grooves 506 are filled with filled with acoustic damping material, i.e. forming a sandwich of the Si substrate 502, the damping material (filled in the groove 506), and the Si wafer 509.

An illustration of a substrate with chamfers according to an embodiment of the present system is shown in FIG. 6. The transducer 600 shown in FIG. 6 includes one or more of a substrate 602, an interconnect layer 690 as desired, and transducer elements 606. The interconnection layer 690 provides connection among various elements, such as between a controller, such as an Application-Specific Integrated Circuit (ASIC) chip and the transducer elements. Illustratively, the interconnection layer 690 comprises epoxy with embedded metal interconnections to provide electrical connection and/or mechanical support. The transducer elements 604 have a height and a width and are separated from each other by one or more trenches 606 having a height and a width. Although empty trenches 606 are shown, the trenches 606 may include elements such as, for example, control conduit, fillers, etc.

In embodiment where the layer 690 is present, it is situated between the substrate 602 and the ultrasonic elements 604, and may formed using a flip-chip interconnection process well-known in the Integrated Chip (IC) industry. For example, metallic bumps may be attached to the IC, and the bumps are attached to the transducer material using conductive epoxy. Next, an epoxy underfill material is flowed into the remaining space and cured.

As shown in FIG. 6, the substrate 602 has a top portion 605, a bottom portion 603, and edges 630. The substrate 602 may be formed from any suitable material and may, for example, include any suitable semiconductor material (e.g., Si). The one or more of the edges 630 of the substrate 602 may include one or more attenuating portions such as, for example, chamfers 634 which are shaped and sized so as to attenuate desired spurious signals. The bottom 603 of the substrate 602 may include an attenuation pattern 692 which may or may not extend to one or more of the edges 630.

A top view illustration of a substrate with non-parallel sides according to an embodiment of the present system 700 is shown in FIG. 7. The substrate 702 has a top portion 705, a bottom portion, and one or more edges 730A-D defining an outer periphery. A transducer array such as an ultrasonic transducer array 704 may be situated on the top portion 705 of the substrate 702. The edges 730A, 730B, 730C, and/or 730D may include shapes suitable for attenuating spurious signals. For example, side edges 730A and 730C may include straight portions and are non-parallel with each other. Accordingly, waves which reflect between the non-parallel side edges (i.e., 730A and 730C) will dissipate more quickly than if the edges are parallel. Further, variations of non-parallel edges may include curved, saw-tooth, or other types of uneven edges. For example, the upper edge 730D may have a curved shape and lower edge 730B is roughened, which may have a saw-tooth shape, for example. The ultrasonic transducer array 704 may be situated on the substrate 702 such that it may be closer to portions of the outer periphery of the substrate 702 than to other portions of the outer periphery, such as closer to the lower edge 730B than to the upper edge 730D, for example. Moreover, the substrate 704 may include an attenuation pattern on its bottom side. Although a substrate 702 having four edges is shown in FIG. 7, it is also envisioned that the substrate may have 3 or more sides. Further the sides may have equal lengths or may be different from each other. The substrate 704 may be formed from any suitable semiconductor material.

It is also envisioned that the edges of the one or more substrates may be matched to, or correspond with, edges of other adjacent substrates. For example, two adjacent substrates may include a saw-tooth edge which can intermesh with each other. This is more clearly illustrated with reference to FIG. 8 where a top view illustration of a transducer array according to an embodiment of the present system is shown. Transducer array 800 includes a plurality of substrates 802-1 to 802-4 having transducer elements 804. The substrates 802-1 to 802-4 have corresponding edges 830 such that the substrates can be placed adjacent to each other.

The substrate(s) should be shaped and sized such that its thickness, which may be the thickness between the upper and lower surfaces in an embodiment where there are no grooves. In such an embodiment without grooves, thickness (and/or shape/size) of the substrate(s) is chosen to be suitable for causing interference and thus, leads to high loss in the propagation of the modes. Although other thicknesses are envisioned, a suitable thickness range for substrates may, for example, be between 30 and 100 microns. Accordingly, acoustic modes may leak energy into a backing-type supporting structure behind the IC which may include lossy materials having high acoustic loss. For this to be effective, the lossy material should have an acoustic velocity lower than the acoustic mode being suppressed.

A process 900 of forming the transducer according to an embodiment of the present system is shown in FIG. 9. The process 900 can include one of more of the following steps, acts or operations. Further, one or more of these steps may be combined and/or separated into sub-steps, if desired.

In step A, a semiconductor substrate 902 such as Silicon (Si) shown as a side view and having a desired shape and size is prepared and cleaned. The substrate 902 comprises the integrated circuit(s) containing the electronics to drive the transducer elements.

In step B, an optional mask 913 may be applied to a surface of the substrate 902.

In step C, voids (which can include trenches, grooves, or other predetermined patterns) 922 may be defined in the substrate 902 by removing portions of the substrate 902, the portions may be removed using any suitable method such as, for example, chemical and/or mechanical etching, machining or sawing. The voids 922 define raised areas or mesas 924 which may be situated between the voids 922.

In step D, the optional mask 913 may be removed from the substrate 902.

In step E, areas along the edges 930 of the substrate 902 may be removed so as to define a shape (suitable for attenuating a spurious signal) such as a chamfer 934, a saw-tooth pattern, etc. This may be done by a machining and/or a grinding process.

In between steps D and E, one or more other layers may be applied to the substrate so as to eventually form further layers, as desired, between layers 902 and 909 (described in connection with step G). The various layers may be formed by conventional sawing, machining, and/or lapping processes. Alternatively or in addition, the various layers may be cast in place so as to fill the voids 922, and then machined to any desired thickness. Likely materials should have high acoustical attenuation, for example, epoxies loaded with solid and/or rubbery particles, or polymer-impregnated porous solids. In general, any layer not cast in place would be glued to the assembly using well known methods of transducer manufacture.

In step F, an optional semiconductor wafer 909 may be applied to, or formed on, the substrate 902. The semiconductor wafer 909 should have a thickness such that it provides necessary rigidity to the substrate 902 during processing.

In step G, an array of transducer elements 904 are attached to or formed on the substrate 902, such as described in U.S. Patent Application Publication No. 2006/0116584 to Sudol, entitled “Miniaturized Ultrasonic Transducer,” which is incorporated herein by reference in its entirety. This step may also include forming vias and/or control circuits to activate and/or receive signals from the transducer substrate 902. Further, this step may also include forming acoustic layers and/or other circuitry on the substrate 902. In one embodiment, the substrate 902 comprises an integrated circuit, completely formed prior to this process 900. Any additional “circuitry” in step G would be electrical interconnections between the IC and the transducer elements, for example.

In step H, the substrate 902 shown in a top view and/or the attached semiconductor wafer 909 may be diced to define a shape of a completed chip or integrated circuit (IC) 900H.

While the present system has been described with reference to transducers, the present invention may also be compatible with other types of ICs which may include systems on chip (SOC) components such as power supplies, amplifiers, solid-state memory, etc.

Certain additional advantages and features of this invention may be apparent to those skilled in the art upon studying the disclosure, or may be experienced by persons employing the novel system and method of the present invention. Of course, it is to be appreciated that any one of the above embodiments or processes may be combined with one or more other embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may comprise hardware portions (e.g., including discrete and integrated electronic circuitry), software portions (e.g., computer programming), and any combination thereof;

f) hardware portions may comprise one or both of analog and digital portions;

g) any of the disclosed devices or portions thereof may be combined together or separated into further portions unless specifically stated otherwise;

h) no specific sequence of acts or steps is intended to be required unless specifically indicated; and

i) the term “plurality of” an element includes two or more of the claimed element, and does not imply any particular range of number of elements; that is, a plurality of elements may be as few as two elements, and may include an immeasurable number of elements.

1. An integrated circuit (IC) apparatus, comprising:
a substrate having opposed first and second major sides and one or more edges defining an outer periphery of the substrate, the substrate comprising a semiconductor material;
one or more transducers situated on the first major side of the substrate; and
an attenuation pattern formed in one or more of the edges of the substrate.

2. The IC apparatus of claim 1, wherein the attenuation pattern further comprises grooves which are formed in the second major side of the substrate.

3. The IC apparatus of claim 1, wherein the attenuation pattern comprises one or more of a chamfer, a round, and a saw-tooth pattern formed in at least one of the one or more edges of the substrate.

4. The IC apparatus of claim 1, wherein the attenuation pattern further comprises an array of trenches defining mesas on the second major side of the substrate.

5. The IC apparatus of claim 4, wherein a distance between adjacent trenches or mesas varies.

6. The IC apparatus of claim 1, wherein the substrate comprises opposing non-parallel and non-adjacent sides.

7. The IC apparatus of claim 1, further comprising an attenuation material attached to at least one of the one or more of the edges, wherein the attenuation material comprises a polymer.

8. The IC apparatus of claim 1, further comprising an acoustic substrate situated between the first major side of the substrate and the one or more transducers.

9. The IC apparatus of claim 1, wherein the attenuation pattern further comprises grooves which are formed in the second major side of the substrate, the IC apparatus further comprising a wafer formed from a semiconductor material which superposes the second major side of the substrate such that the grooves are situated between the wafer and the first side of the substrate.

10. A method for forming a transducer, the method comprising the acts of:
forming edges on a semiconductor substrate which define a closed area having opposed first and second major surfaces;
removing portions of one or more edges of the semiconductor substrate so as to form an attenuation pattern configured to attenuate spurious signals in the semiconductor substrate; and
forming a transducer array on the first major surface of the semiconductor substrate.

11. The method of claim 10, further comprising removing portions from the second major surface of the semiconductor substrate so as to form another attenuation pattern configured to attenuate spurious signals in the semiconductor substrate.

12. The method of claim 11, further comprising superposing a wafer on the second major surface of the semiconductor surface.

13. The method of claim 10, wherein removing portions of one more of the edges forms a sawtooth or curved profile in corresponding edges.

14. The method of claim 11, wherein the removing act comprises forming voids comprising grooves which define peaks or trenches which define mesas.

15. An integrated circuit (IC) apparatus, comprising:
a transducer array comprising a plurality of piezo-electric transducers (PZTs);
a semiconductor substrate having opposed first and second major portions defined by edges, the transducer array being located on the first major portion; and
an attenuation pattern located on one or more edges of the semiconductor substrate, the attenuation pattern configured to attenuate spurious signals within the semiconductor substrate.

16. The IC apparatus of claim 15, further comprising a wafer superposed upon the second major portion of the semiconductor substrate.

17. The IC apparatus of claim 15, wherein the PZTs comprise a capacitive micro-machined ultrasonic transducer (cMUT) array or a piezo micro-machined ultrasonic transducer (pMUT) array.

18. The IC apparatus of claim 15, wherein one or more edges of the semiconductor substrate comprises a chamfered portion.

19. The IC apparatus of claim 15, wherein the attenuation pattern further comprises intersecting grooves or trenches located on the second major portion of the semiconductor substrate.

20. The IC apparatus of claim 15, further wherein the thickness of the semiconductor substrate is between 30 and 100 microns.
